(19) United States
(12) Patent Application Publication
(10) Pub. No.: US 2026/0156938 A1
(43) Pub. Date: Jun. 4, 2026

(54) DISPLAY SUBSTRATE, DISPLAY PANEL, AND DISPLAY DEVICE

(71) Applicants: Hefei Xinsheng Optoelectronics Technology Co., Ltd., Hefei, Anhui (CN); BOE Technology Group Co., Ltd., Beijing (CN)

(72) Inventors: Ruifang Du, Beijing (CN); Xiaoye Ma, Beijing (CN); Yongcan Wang, Beijing (CN); Biqi Li, Beijing (CN)

(73) Assignees: Hefei Xinsheng Optoelectronics Technology Co., Ltd., Hefei, Anhui (CN); BOE Technology Group Co., Ltd., Beijing (CN)

(21) Appl. No.: 18/716,731

(22) PCT Filed: Aug. 31, 2023
(86) PCT No.: PCT/CN2023/116313

§ 371 Date: Jun. 5, 2024

(51) Int. Cl. H10D 86/40; G06F 3/041; H10D 86/60

(52) U.S. Cl. CPC H10D 86/441; G06F 3/0412; H10D 86/60

(57) ABSTRACT

Disclosed are a display substrate, a display panel and a display device. The display substrate includes a base substrate, and a display region and a frame region located on a side of the base substrate. The display region includes a plurality of scanning signal lines extending in a first direction, and a plurality of transfer signal lines and a plurality of data signal lines extending in a second direction crossing the first direction. The scanning signal lines and the data signal lines are provided on different layers, the scanning signal lines and the transfer signal lines are provided on different layers, the data signal lines and the transfer signal lines are provided on the same layer, the scanning signal lines are connected to at least one of the transfer signal lines, and different scanning signal lines are connected to different transfer signal lines.

### FIELD

The disclosure relates to the technical field of displays, and more particularly, to a display substrate, a display panel, and a display device.

### BACKGROUND

With the development of display technology, the market demands for display screens become higher and higher, for example, the size of the frame of the display screen becomes smaller and smaller.

### SUMMARY

The disclosure provides a display substrate, including a base substrate, a display region, and a frame region located on a side of the base substrate, wherein the display region includes:
a plurality of scanning signal lines extending in a first direction, a plurality of transfer signal lines extending in a second direction, and a plurality of data signal lines extending in the second direction, the first direction and the second direction crossing each other;
wherein the scanning signal lines and the data signal lines are provided on different layers, the scanning signal lines and the transfer signal lines are provided on different layers, the data signal lines and the transfer signal lines are provided on the same layer, the scanning signal line is connected to at least one of the transfer signal lines, and different scanning signal lines are connected to different transfer signal lines.

In some embodiments, the plurality of scanning signal lines include a first scanning signal line and a second scanning signal line, and a quantity of transfer signal lines connected to the first scanning signal line is equal to a quantity of transfer signal lines connected to the second scanning signal line.

In some embodiments, the plurality of transfer signal lines are divided into a plurality of transfer line groups arranged in the first direction, and the transfer line groups include one or more adjacent transfer signal lines; and
transfer signal lines located in the same transfer line group are connected to the same scanning signal terminal and the same scanning signal line, and transfer signal lines located in different transfer line groups are connected to different scanning signal terminals and different scanning signal lines.

In some embodiments, the plurality of scanning signal lines include a third scanning signal line and a fourth scanning signal line, and the same quantity of transfer line groups are provided between two transfer line groups connected to and adjacent to the third scanning signal line, and between two transfer line groups connected to and adjacent to the fourth scanning signal line.

In some embodiments, the plurality of scanning signal lines include a fifth scanning signal line and a sixth scanning signal line, a first quantity of transfer line groups are provided between two transfer line groups connected to and adjacent to the fifth scanning signal line, a second quantity of transfer line groups are provided between two transfer line groups connected to and adjacent to the sixth scanning signal line, and the first quantity is greater than or less than the second quantity.

In some embodiments, the plurality of scanning signal lines further include a seventh scanning signal line, the sixth scanning signal line is located between the fifth scanning signal line and the seventh scanning signal line, and a third quantity of transfer line groups are provided between two transfer line groups connected to and adjacent to the seventh scanning signal line; and
wherein the first quantity, the second quantity, and the third quantity increase or decrease in sequence.

In some embodiments, the plurality of transfer line groups include a first transfer line group, a second transfer line group and a third transfer line group which are connected to the same scanning signal line and are sequentially arranged in the first direction; and
wherein a quantity of transfer line groups provided between the first transfer line group and the second transfer line group is equal to a quantity of transfer line groups provided between the second transfer line group and the third transfer line group.

In some embodiments, the plurality of scanning signal lines include an eighth scanning signal line, and the plurality of transfer line groups include a fourth transfer line group, a fifth transfer line group and a sixth transfer line group which are connected to the eighth scanning signal line and are sequentially arranged in the first direction; and
a fourth quantity of transfer line groups are provided between the fourth transfer line group and the fifth transfer line group, a fifth quantity of transfer line groups are provided between the fifth transfer line group and the sixth transfer line group, and the fourth quantity is greater than or less than the fifth quantity.

In some embodiments, the plurality of scanning signal lines further include a ninth scanning signal line, and the plurality of transfer line groups further include a seventh transfer line group, an eighth transfer line group and a ninth transfer line group which are connected to the ninth scanning signal line and are sequentially arranged in the first direction;
a sixth quantity of transfer line groups are provided between the seventh transfer line group and the eighth transfer line group, and a seventh quantity of transfer line groups are provided between the eighth transfer line group and the ninth transfer line group; and
wherein the fourth quantity is greater than the fifth quantity and the sixth quantity is less than the seventh quantity, or the fourth quantity is less than the fifth quantity and the sixth quantity is greater than the seventh quantity.

In some embodiments, the plurality of transfer line groups include a tenth transfer line group and an eleventh transfer line group connected to the same scanning signal line, the tenth transfer line group and the eleventh transfer line group are axially symmetrically provided about a first axis, and the first axis is a symmetry axis extending in the second direction of an orthographic projection of the display region on the base substrate.

In some embodiments, the scanning signal lines and the transfer signal lines are connected via transfer holes, and transfer holes connecting all transfer signal lines in the same transfer line group constitute a transfer hole group; and
in an orthographic projection on the base substrate, a plurality of transfer hole groups are arranged in a shape including at least one of the following: a V-shape, an inverted V-shape, an N-shape, an inverted N-shape, a strip extending in a third direction, a plurality of strips extending in the third direction and parallel to each other, and the third direction is provided crosswise to the first direction and the second direction, respectively.

In some embodiments, a quantity of transfer signal lines contained in the transfer line group is M or M+1, the M is a positive integer obtained by rounding down m*3/(2N*2n), the m is a row resolution of the display region, the n is a column resolution of the display region, and the N is a quantity of transfer line groups connected to the same scanning signal line; and/or
difference between quantities of transfer signal lines contained in different transfer line groups is less than or equal to 1; and/or
quantities of transfer line groups connected to different scanning signal lines are the same.

In some embodiments, wherein the scanning signal lines and the transfer signal lines are connected via transfer holes, and transfer holes connecting all transfer signal lines in the same transfer line group constitute a transfer hole group; and
a plurality of transfer hole groups are divided into a plurality of transfer units arranged in the first direction, each of the transfer units includes the same quantity of transfer hole groups, the plurality of transfer units include a first transfer unit and a second transfer unit, and the first transfer unit and the second transfer unit are translationally symmetric or axially symmetric.

In some embodiments, the display region includes a plurality of sub-pixels arranged in an array in a row direction and a column direction, the row direction is the first direction, and the column direction is the second direction;
the plurality of scanning signal lines include a tenth scanning signal line and an eleventh scanning signal line located on two sides of the same sub-pixel row, the tenth scanning signal line is connected to odd-numbered columns of sub-pixels in the same sub-pixel row, and the eleventh scanning signal line is connected to even-numbered columns of sub-pixels in the same sub-pixel row; and
the data signal lines and the transfer signal lines are alternately provided between two adjacent columns of sub-pixels, one of the data signal lines and the transfer signal lines is provided between two adjacent columns of sub-pixels, and the data signal lines are connected to two columns of sub-pixels located on two sides of and adjacent to the data signal lines.

In some embodiments, the scanning signal lines are located between the transfer signal lines and the base substrate, and the display region further includes:
a common electrode layer located on a side of the transfer signal lines away from the base substrate, including a plurality of common electrodes; and
wherein in an orthographic projection on the base substrate, the common electrode layer covers the transfer signal lines at least in the first direction.

In some embodiments, the scanning signal lines are located between the transfer signal lines and the base substrate, and the display region further includes:
a plurality of touch control signal lines extending in the second direction, wherein the touch control signal lines are located on a side of the data signal lines away from the base substrate, and in an orthographic projection on the base substrate, the touch control signal lines cover the data signal lines at least in the first direction.

In some embodiments, the display region further includes:
a common electrode layer, located between the data signal lines and the touch control signal lines, or located on a side of the touch control signal lines away from the base substrate, including a plurality of touch control sub-blocks separated from each other, wherein the touch control sub-blocks include a plurality of common electrodes connected to each other; and
wherein the touch control sub-blocks are connected to one or more adjacent touch control signal lines via touch control holes, a plurality of touch control signal lines connected to the same touch control sub-block are connected to the same touch control signal terminal, and touch control signal lines connected to different touch control sub-blocks are connected to different touch control signal terminals.

In some embodiments, the common electrode layer is located between the data signal lines and the touch control signal lines, and the display region further includes:
a first pixel electrode layer, located on a side of the touch control signal lines away from the base substrate, including a plurality of first pixel electrodes separated from each other and a transfer electrode separated from the first pixel electrodes; and
the touch control holes including a half hole and a first through hole, wherein the transfer electrode and the touch control signal lines are connected via the half hole, and the transfer electrode and the touch control sub-blocks are connected via the first through hole.

In some embodiments, the plurality of touch control sub-blocks are arranged in an array in the first direction and the second direction, the plurality of touch control sub-blocks are divided into a plurality of touch control regions arranged in the first direction, and the touch control regions include one or more adjacent columns of touch control sub-blocks; and
the plurality of touch control regions include a first touch control region and a second touch control region, and a plurality of touch control holes located in the first touch control region are axially symmetric or translationally symmetric with a plurality of touch control holes located in the second touch control region.

In some embodiments, the frame region includes:
a touch control signal terminal, provided on the same layer as the touch control signal lines and connected to each other, for providing a touch control signal to the touch control signal lines; and
a data signal terminal, provided on the same layer as the data signal lines and connected to each other, for providing a data signal to the data signal lines; and
wherein the touch control signal terminal is located between the plurality of data signal terminals, and the touch control signal terminal and the data signal terminal are both configured for binding a source drive chip.

In some embodiments, the frame region includes:
a scanning signal terminal, provided on the same layer as the scanning signal lines and connected to the transfer signal lines through a via hole, for providing a scanning signal to the transfer signal lines and the scanning signal lines; and
a data signal terminal, provided on the same layer as the data signal line and connected to each other, for providing a data signal to the data signal lines; and
wherein the scanning signal terminal and the data signal terminal are located on the same side of the display region.

In some embodiments, a plurality of the scanning signal terminals are divided into one or more scanning signal binding areas which are configured for binding a gate drive chip;
a plurality of the data signal terminals are divided into a plurality of data signal binding areas, and the data signal binding areas which are configured for binding a source drive chip; and
wherein the scanning signal binding areas are provided between two adjacent data signal binding areas, and at most one of the scanning signal binding areas is provided between two adjacent data signal binding areas, and at most two of the data signal binding areas are provided between two adjacent scanning signal binding areas.

In some embodiments, the plurality of data signal binding areas include a first data signal binding area and a second data signal binding area which are provided close to a first edge or a second edge, and the first edge and the second edge are two edges of the display substrate opposite in the first direction; and
the scanning signal binding area is provided between the first data signal binding area and the second data signal binding area.

The disclosure provides a display panel, including: a cell alignment substrate, a liquid crystal layer, and the display substrate according to any one of implementations, wherein the liquid crystal layer is located between the cell alignment substrate and the display substrate, and the display region is provided close to the liquid crystal layer.

The disclosure provides a display device, including:
the display substrate according to any one of implementations;
a source drive chip, bound and connected to the frame region, for providing a data signal to the data signal line; and one of the following:
a gate drive chip, bound and connected to the frame region, and located on the same side of the display region as the source drive chip, for providing a scanning signal to the transfer signal line and the scanning signal line;
a gate drive circuit, located in the frame region, and located on the same side of the display region as the source drive chip, for providing a scanning signal to the transfer signal line and the scanning signal line.

The above description is only an overview of the technical solution of the present application. In order to have a clearer understanding of the technical means of the present application, it can be implemented according to the content of the specification. In order to make the above and other purposes, features, and advantages of the present application more obvious and easier to understand, the specific implementations of the present application are listed below.

### BRIEF DESCRIPTION OF THE DRAWINGS

In order to more clearly illustrate the technical solutions of the embodiments of the present application, the figures that are required to describe the embodiments of the present application will be briefly described below. Apparently, the figures that are described below are merely a part of the embodiments of the present application, and a person skilled in the art can obtain other figures according to these figures without paying creative work. It should be noted that the scale in the figures is only for illustrative purposes and do not represent the actual scale.

FIG. 1 schematically shows a schematic view of a plane structure of a display substrate provided by the disclosure;

FIG. 2 schematically shows a circuit layout of a first display region;

FIG. 3 schematically shows a circuit layout of a second display region;

FIG. 4 schematically shows a schematic view of an arrangement structure of a plurality of transfer hole groups;

FIG. 5 schematically shows another schematic view of the arrangement structure of the plurality of transfer hole groups;

FIG. 6 schematically shows a circuit layout at an intersection of a display region and a frame region;

FIG. 7 schematically shows a schematic view of a cross-sectional structure of the first display region at different positions;

FIG. 8 schematically shows a schematic view of a cross-sectional structure of the second display region at different positions;

FIG. 9 schematically shows a schematic view of an arrangement of a touch control unit in the display region;

FIG. 10 schematically shows a schematic view of an arrangement of a touch control hole in a touch control sub-block;

FIG. 11 schematically shows a plan structure view of a first pixel electrode layer, and a partially enlarged view of a display substrate at a position of the touch control hole;

FIG. 12 schematically shows a schematic view of a preparing process of the first display region and the second display region;

FIG. 13 schematically shows a circuit layout of a touch control signal terminal and a data signal terminal;

FIG. 14 schematically shows a circuit layout of a scanning signal terminal;

FIG. 15 schematically shows a schematic view of wiring of the frame region;

FIG. 16 schematically shows a circuit layout of a transfer signal line and a first lead;

FIG. 17 schematically shows a schematic view of structures of the first lead, a second lead, and a third lead; and

FIG. 18 schematically shows a schematic view of structures of a scanning signal binding area and a data signal binding area.

### DETAILED DESCRIPTION

The technical solutions according to the embodiments of the present application will be clearly and completely described below with reference to the drawings according to the embodiments of the present application. Apparently, the described embodiments are merely a part of the embodiments of the present application, rather than all of the embodiments. All of the other embodiments that a person skilled in the art obtains on the basis of the embodiments of the present application without paying creative work fall within the protection scope of the present application.

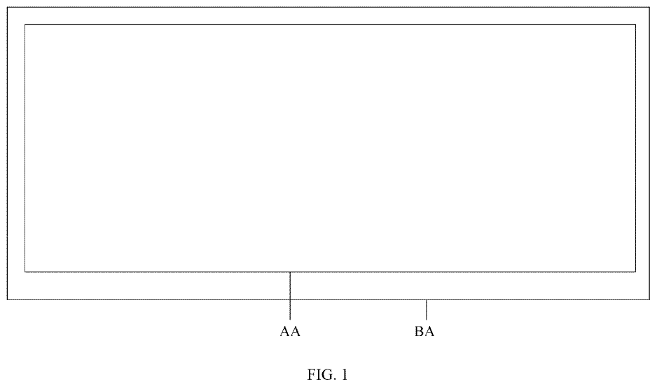

Referring to FIG. 1, a schematic view of a plane structure of a display substrate provided by the present disclosure is illustratively shown. The display substrate includes a base substrate 11 (not shown in FIG. 1), and a display region AA and a frame region BA located on a side of the base substrate 11, as shown in FIG. 1.

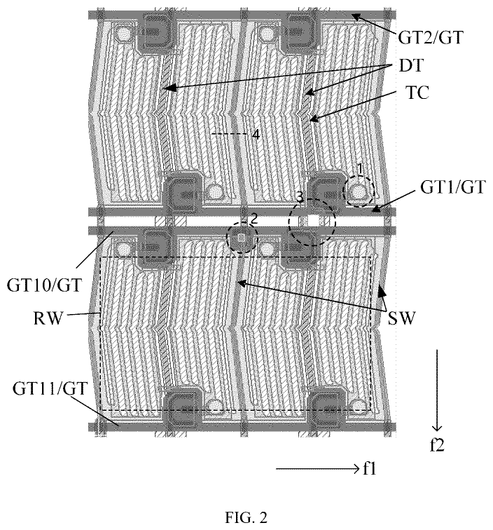

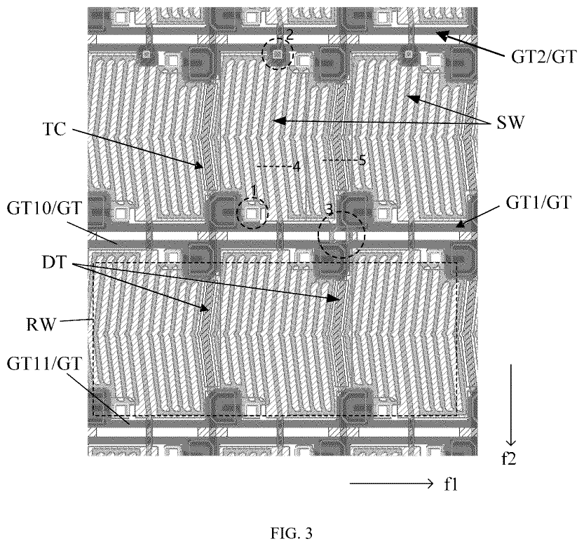

Referring to FIG. 2 and FIG. 3, respectively, two circuit layouts of the display region are schematically shown. As shown in FIG. 2 or FIG. 3, respectively, the display region AA includes a plurality of scanning signal lines GT extending in a first direction f1, a plurality of transfer signal lines SW extending in a second direction f2, and a plurality of data signal lines DT extending in the second direction f2, where the first direction f1 and the second direction f2 cross each other.

The scanning signal line GT and the data signal line DT are provided on different layers, the scanning signal line GT and the transfer signal line SW are provided on different layers, the data signal line DT and the transfer signal line SW are provided on the same layer, the scanning signal line GT is connected to at least one transfer signal line SW, and different scanning signal lines GT are connected to different transfer signal lines SW.

In the display substrate provided by the disclosure, since the scanning signal line GT is connected to the transfer signal line SW, and both the transfer signal line SW and the data signal line DT extend in the second direction f2, a gate drive circuit or a gate drive chip can be provided on the same side of the display region AA as the source drive circuit, so that the size of two side frames of the display substrate which are oppositely provided in the first direction f1 can be reduced. The gate drive circuit and the gate drive chip are used for generating a scanning signal, which is transmitted to the scanning signal line GT via the transfer signal line SW. The source drive circuit is used for providing a data signal to the data signal line DT.

Illustratively, as shown in FIG. 2 or FIG. 3, the first direction f1 and the second direction f2 are perpendicular to each other.

Illustratively, as shown in FIG. 2 or FIG. 3, the plurality of scanning signal lines GT are arranged in the second direction f2, and the plurality of transfer signal lines SW and the plurality of data signal lines DT are arranged in the first direction f1.

Illustratively, each scanning signal line GT within the display region AA is connected to one or more transfer signal lines SW.

In some embodiments, as shown in FIG. 2 or FIG. 3, the plurality of scanning signal lines GT include a first scanning signal line GT1 and a second scanning signal line GT2, and the quantity of transfer signal lines SW connected to the first scanning signal line GT1 is equal to the quantity of transfer signal lines SW connected to the second scanning signal line GT2. In this way, consistent driving of different scanning signal lines GT can be ensured to improve display uniformity.

The first scanning signal line GT1 and the second scanning signal line GT2 may be any two different scanning signal lines GT.

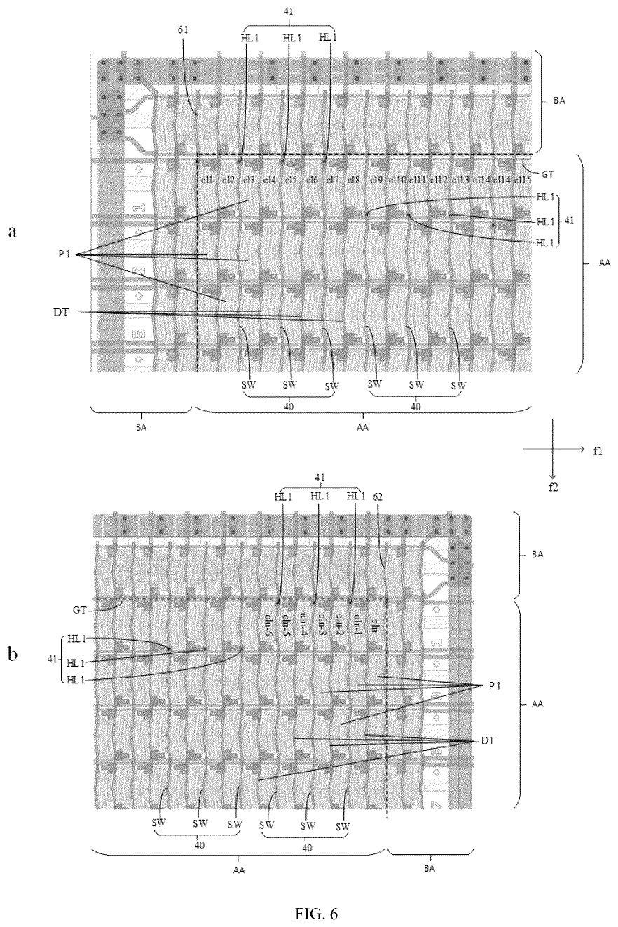

In some embodiments, as shown in FIG. 6, the plurality of transfer signal lines SW are divided into a plurality of transfer line groups 40 arranged in the first direction f1. The transfer line groups 40 include one or more adjacent transfer signal lines SW. The transfer signal lines SW located in the same transfer line group 40 are connected to the same scanning signal terminal PING and the same scanning signal line GT, and the transfer signal lines SW located in different transfer line groups 40 are connected to different scanning signal terminals PING and different scanning signal lines GT. The scanning signal terminals PING are located in the frame region BA.

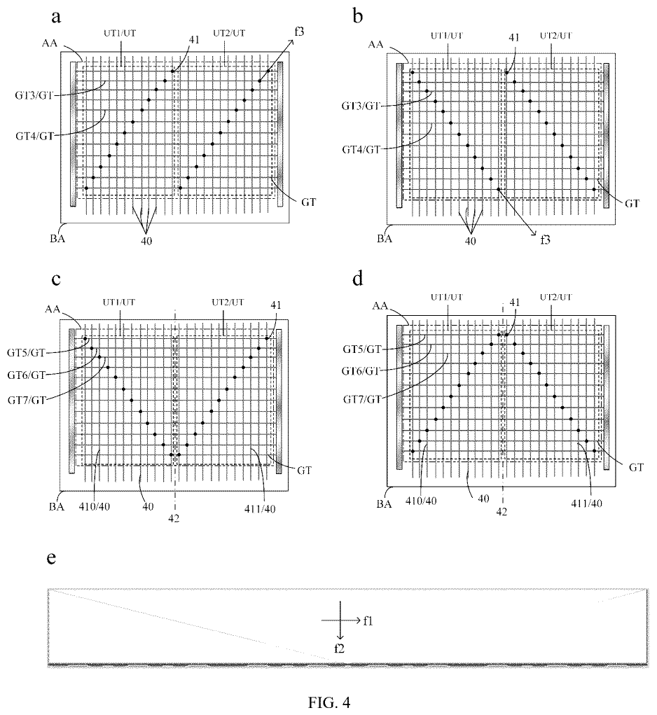

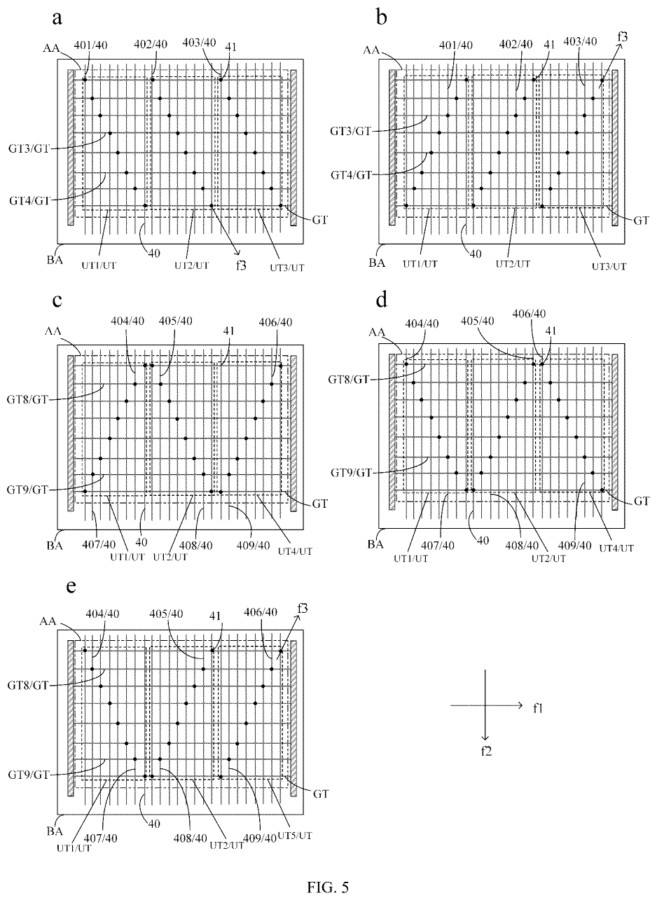

In some embodiments, as shown in FIG. 4 or FIG. 5, the plurality of scanning signal lines GT include a third scanning signal line GT3 and a fourth scanning signal line GT4. The same quantity of transfer line groups 40 are provided between two transfer line groups 40 connected to and adjacent to the third scanning signal line GT3 and between two transfer line groups 40 connected to and adjacent to the fourth scanning signal line GT4.

The third scanning signal line GT3 and the fourth scanning signal line GT4 may be any two different scanning signal lines GT.

Illustratively, as shown in panel a or panel b of FIG. 4, eleven transfer line groups 40 are provided between two transfer line groups 40 connected to and adjacent to the third scanning signal line GT3, and eleven transfer line groups 40 are also provided between two transfer line groups 40 connected to and adjacent to the fourth scanning signal line GT4.

Illustratively, as shown in panel a or panel b of FIG. 5, seven transfer line groups 40 are provided between two transfer line groups 40 connected to and adjacent to the third scanning signal line GT3, and seven transfer line groups 40 are also provided between two transfer line groups 40 connected to and adjacent to the fourth scanning signal line GT4.

In some embodiments, as shown in FIG. 4, the plurality of scanning signal lines GT include a fifth scanning signal line GT5 and a sixth scanning signal line GT6. A first quantity of transfer line groups 40 are provided between two transfer line groups 40 connected to and adjacent to the fifth scanning signal line GT5, and a second quantity of transfer line groups 40 are provided between two transfer line groups 40 connected to and adjacent to the sixth scanning signal line GT6. The first quantity is greater than or less than the second quantity.

The fifth scanning signal line GT5 and the sixth scanning signal line GT6 may be any two different scanning signal lines GT.

Illustratively, as shown in panel c of FIG. 4, twenty-two transfer line groups 40 are provided between two transfer line groups 40 connected to and adjacent to the fifth scanning signal line GT5, and twenty transfer line groups 40 are also provided between two transfer line groups 40 connected to and adjacent to the sixth scanning signal line GT6, namely, the first quantity is 22, the second quantity is 20, and the first quantity is greater than the second quantity.

Illustratively, as shown in panel d of FIG. 4, zero transfer line groups 40 are provided between two transfer line groups 40 connected to and adjacent to the fifth scanning signal line GT5, and two transfer line groups 40 are also provided between two transfer line groups 40 connected to and adjacent to the sixth scanning signal line GT6, namely, the first quantity is 0, the second quantity is 2, and the first quantity is less than the second quantity.

In some embodiments, as shown in FIG. 4, the plurality of scanning signal lines GT further include a seventh scanning signal line GT7. The sixth scanning signal line GT6 is located between the fifth scanning signal line GT5 and the seventh scanning signal line GT7, and a third quantity of transfer line groups 40 are provided between two transfer line groups 40 connected to and adjacent to the seventh scanning signal line GT7. The first quantity, the second quantity and the third quantity increase or decrease in sequence.

Illustratively, as shown in panel c of FIG. 4, eighteen transfer line groups 40 are provided between two transfer line groups 40 connected to and adjacent to the seventh scanning signal line GT7, i.e. the first quantity is 22, the second quantity is 20, the third quantity is 18, and the first quantity, the second quantity, and the third quantity decrease in sequence.

Illustratively, as shown in panel d of FIG. 4, four transfer line groups 40 are provided between two transfer line groups 40 connected to and adjacent to the seventh scanning signal line GT7, i.e., the first quantity is 0, the second quantity is 2, the third quantity is 4, and the first quantity, the second quantity and the third quantity increase successively.

The fifth scanning signal line GT5, the sixth scanning signal line GT6, and the seventh scanning signal line GT7 may be any three different scanning signal lines GT.

In some embodiments, as shown in FIG. 5, the plurality of transfer line groups 40 includes a first transfer line group 401, a second transfer line group 402, and a third transfer line group 403 which are connected to the same scanning signal line GT and are arranged in sequence in the first direction f1. The quantity of transfer line groups 40 provided between the first transfer line group 401 and the second transfer line group 402 is equal to the quantity of transfer line groups 40 provided between the second transfer line group 402 and the third transfer line group 403.

The first transfer line group 401, the second transfer line group 402 and the third transfer line group 403 may be three adjacent transfer line groups 40 in a plurality of transfer line groups 40 connected to the same scanning signal line GT.

Illustratively, the quantity of transfer line groups 40 provided between the first transfer line group 401 and the second transfer line group 402 is seven, and the quantity of transfer line groups 40 provided between the second transfer line group 402 and the third transfer line group 403 is also seven, as shown in panel a or panel b of FIG. 5.

In some embodiments, as shown in panel c to panel e of FIG. 5, the plurality of scanning signal lines GT include an eighth scanning signal line GT8, and the plurality of transfer line groups 40 include a fourth transfer line group 404, a fifth transfer line group 405, and a sixth transfer line group 406 which are connected to the eighth scanning signal line GT8 and are arranged in sequence in the first direction f1. A fourth quantity of transfer line groups 40 is provided between the fourth transfer line group 404 and the fifth transfer line group 405, a fifth quantity of transfer line groups 40 is provided between the fifth transfer line group 405 and the sixth transfer line group 406, and the fourth quantity is greater than or less than the fifth quantity.

The fourth transfer line group 404, the fifth transfer line group 405 and the sixth transfer line group 406 may be three adjacent transfer line groups 40 in a plurality of transfer line groups 40 connected to the eighth scanning signal line GT8.

In some embodiments, as shown in panel c to panel e of FIG. 5, the plurality of scanning signal lines GT further include a ninth scanning signal line GT9, and the plurality of transfer line groups 40 include a seventh transfer line group 407, an eighth transfer line group 408, and a ninth transfer line group 409 which are connected to the ninth scanning signal line GT9 and are sequentially arranged in the first direction f1. A sixth quantity of transfer line groups 40 is provided between the seventh transfer line group 407 and the eighth transfer line group 408, and a seventh quantity of transfer line groups 40 is provided between the eighth transfer line group 408 and the ninth transfer line group 409. The fourth quantity is greater than the fifth quantity, and the sixth quantity is less than the seventh quantity; alternatively, the fourth quantity is less than the fifth quantity and the sixth quantity is greater than the seventh quantity.

The eighth scanning signal line GT8 and the ninth scanning signal line GT9 may be any two different scanning signal lines GT.

The seventh transfer line group 407, the eighth transfer line group 408 and the ninth transfer line group 409 may be three adjacent transfer line groups 40 in a plurality of transfer line groups 40 connected to the ninth scanning signal line GT9.

Illustratively, as shown in panel c of FIG. 5, two transfer line groups 40 are provided between the fourth transfer line group 404 and the fifth transfer line group 405, and twelve transfer line groups 40 are provided between the fifth transfer line group 405 and the sixth transfer line group 406, i.e., the fourth quantity is 2, the fifth quantity is 12, and the fourth quantity is less than the fifth quantity. Twelve transfer line groups 40 are provided between the seventh transfer line group 407 and the eighth transfer line group 408, and two transfer line groups 40 are provided between the eighth transfer line group 408 and the ninth transfer line group 409, i.e., the sixth quantity is 12, the seventh quantity is 2, and the sixth quantity is greater than the seventh quantity.

Illustratively, as shown in panel d of FIG. 5, fourteen transfer line groups 40 are provided between the fourth transfer line group 404 and the fifth transfer line group 405, and zero transfer line groups 40 are provided between the fifth transfer line group 405 and the sixth transfer line group 406, i.e., the fourth quantity is 14, the fifth quantity is 0, and the fourth quantity is greater than the fifth quantity. Four transfer line groups 40 are provided between the seventh transfer line group 407 and the eighth transfer line group 408, and ten transfer line groups 40 are provided between the eighth transfer line group 408 and the ninth transfer line group 409, i.e., the sixth quantity is 4, the seventh quantity is 10, and the sixth quantity is less than the seventh quantity.

Illustratively, as shown in panel e of FIG. 5, twelve transfer line groups 40 are provided between the fourth transfer line group 404 and the fifth transfer line group 405, and seven transfer line groups 40 are provided between the fifth transfer line group 405 and the sixth transfer line group 406, i.e. the fourth quantity is 12, the fifth quantity is 7, and the fourth quantity is greater than the fifth quantity. Two transfer line groups 40 are provided between the seventh transfer line group 407 and the eighth transfer line group 408, and seven transfer line groups 40 are provided between the eighth transfer line group 408 and the ninth transfer line group 409, namely, the sixth quantity is 2, the seventh quantity is 7, and the sixth quantity is less than the seventh quantity.

In some embodiments, as shown in panel c or panel d of FIG. 4, the plurality of transfer line groups 40 include a tenth transfer line group 410 and an eleventh transfer line group 411 which are connected to the same scanning signal line GT. The tenth transfer line group 410 and the eleventh transfer line group 411 are symmetrically provided with respect to the first axis 42, and the first axis 42 is a symmetry axis extending in the second direction f2 of an orthographic projection of the display region AA on the base substrate 11.

In some embodiments, as shown in FIG. 6, the scanning signal line GT is connected to the transfer signal line SW through a transfer hole HT1, and the transfer holes HT1 connecting all the transfer signal lines SW in the same transfer line group 40 constitute a transfer hole group 41.

In some embodiments, as shown in FIG. 4 or FIG. 5, a plurality of transfer hole groups 41 is divided into a plurality of transfer units UT arranged in the first direction f1, each transfer unit UT includes the same quantity of transfer hole groups 41, the plurality of transfer units UT includes a first transfer unit UT1 and a second transfer unit UT2, and the first transfer unit UT1 and the second transfer unit UT2 are translationally symmetric or axially symmetric.

Illustratively, the first transfer unit UT1 is translationally symmetric with the second transfer unit UT2, i.e. the first transfer unit UT1 can substantially coincide with the second transfer unit UT2 by translating in the first direction f1, as shown in panel a or panel b of FIG. 4.

Illustratively, the first transfer unit UT1 is axially symmetric with the second transfer unit UT2, and the symmetry axis is such as the first axis 42, as shown in panel c or panel d of FIG. 4.

Illustratively, the first transfer unit UT1 is translationally symmetric with the second transfer unit UT2, i.e. the first transfer unit UT1 can substantially coincide with the second transfer unit UT2 by translating in the first direction f1, as shown in panel a or panel b of FIG. 5.

Illustratively, as shown in panel a or panel b of FIG. 5, the plurality of transfer units UT further include a third transfer unit UT3, the second transfer unit UT2 is located between the first transfer unit UT1 and the third transfer unit UT3, the first transfer unit UT1 and the second transfer unit UT2 are respectively translationally symmetric with the third transfer unit UT3, i.e. the first transfer unit UT1 can substantially coincide with the third transfer unit UT3 by translating in the first direction f1, and the second transfer unit UT2 can substantially coincide with the third transfer unit UT3 by translating in the first direction f1.

Illustratively, the first transfer unit UT1 is axially symmetric with the second transfer unit UT2, and the symmetry axis is in the second direction f2, as shown in panel c, panel d, or panel e of FIG. 5.

Illustratively, the plurality of transfer units UT further include a fourth transfer unit UT4, the second transfer unit UT2 is located between the first transfer unit UT1 and the fourth transfer unit UT4, the second transfer unit UT2 is axially symmetric with the fourth transfer unit UT4, and the symmetry axis is in the second direction f2, as shown in panel c or panel d of FIG. 5. The first transfer unit UT1 is translationally symmetric with the fourth transfer unit UT4, i.e. the first transfer unit UT1 can substantially coincide with the fourth transfer unit UT4 by translating in the first direction f1.

Illustratively, the plurality of transfer units UT further includes a fifth transfer unit UT5, the second transfer unit UT2 is located between the first transfer unit UT1 and the fifth transfer unit UT5, the first transfer unit UT1 is axially symmetric with the fifth transfer unit UT5, and the symmetry axis is in the second direction f2, as shown in panel e of FIG. 5. The second transfer unit UT2 is translationally symmetric with the fifth transfer unit UT5, i.e. the second transfer unit UT2 can substantially coincide with the fifth transfer unit UT5 by translating in the first direction f1.

As shown in FIG. 4 or FIG. 5, in the orthographic projection on the base substrate 11, the plurality of transfer hole groups 41 are arranged in a shape including at least one of the following: a V-shape (as shown in panel c of FIG. 4), an inverted V-shape (as shown in panel d of FIG. 4), an N-shape (as shown in panel c of FIG. 5), an inverted N-shape (as shown in panel d of FIG. 5), a strip extending in a third direction f3, and a plurality of strips extending in the third direction f3 and parallel to each other (as shown in FIG. 4 and panel a and panel b of FIG. 5). The third direction f3 is provided crosswise to the first direction f1 and the second direction f2, respectively.

Illustratively, as shown in panel e of FIG. 5, the plurality of transfer hole groups 41 are arranged in a shape of a combination of a V-shape and a strip extending in the third direction f3.

Illustratively, as shown in panel e of FIG. 4, in a display substrate for on-board display, the plurality of transfer hole groups 41 are arranged in a V-shaped shape, the opening of which faces a long side of the display substrate.

In the case where the plurality of transfer hole groups 41 are arranged in a shape of a plurality of strips extending in the third direction f3 and parallel to each other, the driving capability of the plurality of scanning signal lines GT is more uniform, and the charging difference between different scanning signal lines GT is small.

Illustratively, in panel a and panel b of FIG. 4, the plurality of transfer hole groups 41 are arranged in a shape of two strips extending in the third direction f3 and parallel to each other, such as a //shape, a \\shape. In panel a and panel b of FIG. 5, the plurality of transfer hole groups 41 are arranged in a shape of three strips extending in the third direction f3 and parallel to each other, such as a \\\shape, a ///shape.

In a specific implementation, each scanning signal line GT can be connected to the transfer signal lines SW in N transfer line groups 40 to realize N-point driving, where N is a positive integer. The multi-point driving can improve the driving capability of the scanning signal line GT and reduce the signal delay, and the larger the value of N, the stronger the driving capability of the scanning signal line GT.

Illustratively, as shown in FIG. 4, N=2, i.e. each scanning signal line GT is connected to two transfer line groups 40 at different positions to realize two-point driving. In this example, the plurality of transfer hole groups 41 may be arranged in a shape, for example, a V-shape, an inverted V-shape, or two strips extending in the third direction f3 and parallel to each other, such as a //shape, a //shape.

In the plurality of transfer hole groups 41 arranged in a V-shape and an inverted V-shape, two transfer line groups 40 adjacent to an apex are closer to each other, and a scanning signal line GT connected to the two transfer line groups 40 adjacent to the apex is approximately one-point driving. However, in the plurality of transfer hole groups 41 arranged in a //shape or a \\shape, the driving capability of different scanning signal lines GT is more uniform, and the charging difference between the different scanning signal lines GT is small.

Illustratively, as shown in FIG. 5, N=3, i.e., each scanning signal line GT may be connected to a transfer signal line SW in three transfer line groups 40 to realize three-point driving. In this example, the plurality of transfer hole groups 41 may be arranged in a shape, for example, an N-shape, an inverted N-shape, three strips extending in the third direction f3 and parallel to each other, such as a \\\shape, a ///shape, a combination of a V-shape or an inverted V-shape and a strip extending in the third direction f3, such as a V/shape, etc.

In the plurality of transfer hole groups 41 arranged in an N-shape, an inverted N-shape, and a V/shape, two transfer line groups 40 adjacent to an apex are closer to each other, and a scanning signal line GT connected to the two transfer line groups 40 adjacent to the apex is approximately one-point driving. However, in the plurality of transfer hole groups 41 arranged in a \\\shape or a ///shape, the driving capability of different scanning signal lines GT is more uniform, and the charging difference between different scanning signal lines GT is small.

In some embodiments, a quantity of transfer signal lines SW included in the transfer line group 40 is M or M+1 of, M is a positive integer obtained by rounding down m*3/(2N*2n), m is a row resolution of the display region AA, n is a column resolution of the display region AA, and N is a quantity of transfer line groups 40 connected to the same scanning signal lines GT.

In this embodiment, m is a quantity of rows of sub-pixels included in the display region AA, n is a quantity of columns of sub-pixels included in the display region AA, and the same pixel unit may include a plurality of sub-pixels with different colors and arranged in the column direction, such as a red sub-pixel, a green sub-pixel, and a blue sub-pixel.

Illustratively, if m*3/(2N*2n) is divisible, then M=m*3/(2N*2n). If m*3/(2N*2n) is not divisible, then M is a positive integer obtained by rounding down m*3/(2N*2n). In this case, the quantity of the transfer signal lines SW included in a part of transfer line groups 40 is M, and the quantity of the transfer signal lines SW included in the other part of transfer line groups 40 is M+1.

Illustratively, the resolution of the display substrate is 8800*1092, i.e., m=8800, n=1092, two-point driving, i.e., N=2, and M=3 according to the calculation of m*3/(2N*2n), so that the quantity of the transfer signal lines SW included in the transfer line group 40 is 3 or 4, i.e., the quantity of the transfer signal lines SW included in a part of the transfer line groups 40 is 3 (as shown in FIG. 6), and the quantity of the transfer signal lines SW included in another part of the transfer line groups 40 is 4.

In some embodiments, the difference between the quantities of transfer signal lines SW included in different transfer line groups 40 is less than or equal to 1.

Illustratively, the quantities of transfer signal lines SW included in different transfer line groups 40 are the same. In this case, the difference between the quantities of transfer signal lines SW included in the different transfer line groups 40 is equal to 0.

Illustratively, the quantities of transfer signal lines SW included in different transfer line groups 40 are different. For example, the quantity of transfer signal lines SW included in one transfer line group 40 is M, and the quantity of transfer signal lines SW included in another transfer line group 40 is M+1. In this case, the difference between the quantities of transfer signal lines SW included in different transfer line groups 40 is 1.

In some embodiments, the quantities of transfer line groups 40 connected to different scanning signal lines GT are the same. For example, each scanning signal line GT is connected to N transfer line groups 40.

In some embodiments, as shown in FIG. 6, the data signal lines DT and the transfer signal lines SW are arranged alternately in sequence in the first direction f1.

In some embodiments, as shown in FIG. 6, the display region AA includes a plurality of sub-pixels P1 arranged in an array in a row direction and a column direction, and the row direction is the first direction f1 and the column direction is the second direction f2. Each sub-pixel P1 includes, for example, a thin film transistor or the like.

In some embodiments, as shown in FIG. 2 or FIG. 3, the plurality of scanning signal lines GT include a tenth scanning signal line GT10 and an eleventh scanning signal line GT11 located on two sides of the same sub-pixel row RW. The tenth scanning signal line GT10 is connected to odd-numbered columns of sub-pixels in the same sub-pixel row RW, and the eleventh scanning signal line GT11 is connected to even-numbered columns of sub-pixels in the same sub-pixel row RW. In this way, dual-gate driving can be realized, where each sub-pixel row RW is driven by two scanning signal lines GT, and the set quantity of data signal lines DT can be reduced.

Further, as shown in FIG. 2 or FIG. 3, the data signal line DT and the transfer signal line SW are alternately provided between two adjacent sub-pixel columns, and one of the data signal line DT and the transfer signal line SW is provided between the two adjacent sub-pixel columns, and the data signal line DT is connected to two adjacent sub-pixel columns located on both sides of the data signal line DT.

Illustratively, as shown in FIG. 2 or FIG. 3, for each sub-pixel column, the data signal line DT and the transfer signal line SW are located on different sides of the sub-pixel column.

Illustratively, as shown in FIG. 6, the display region AA includes a first sub-pixel column cl1, a second sub-pixel column cl2, a third sub-pixel column cl3, . . . , and a nth sub-pixel column cln arranged in sequence in the first direction f1. The data signal lines DT are located between the first sub-pixel column cl1 and the second sub-pixel column cl2, between the third sub-pixel column cl3 and the fourth sub-pixel column cl4, . . . , and between the (n−1)^{th} sub-pixel column cln−1 and the nth sub-pixel column cln. The transfer signal lines SW are located between the second sub-pixel column cl2 and the third sub-pixel column cl3, between the fourth sub-pixel column cl4 and the fifth sub-pixel column cl5, . . . , and between the (n−2)^{th} sub-pixel column cln−2 and the (n−1)^{th} sub-pixel column cln−1.

Illustratively, as shown in FIG. 6, a first edge transfer line 61 is provided on the side of the first sub-pixel column cl1 away from the second sub-pixel column cl2, and the connection between the first edge transfer line 61 and the scanning signal line GT is the same as the connection between the adjacent transfer signal line SW (i.e., the transfer signal line SW located between the second sub-pixel column cl2 and the third sub-pixel column cl3) and the scanning signal line GT. Similarly, a second edge transfer line 62 is provided on the side of the n^{th} sub-pixel column cln away from the (n−1)^{th} sub-pixel column cln−1, and the connection between the second edge transfer line 62 and the scanning signal line GT is the same as the connection between the adjacent transfer signal line SW (i.e., the transfer signal line SW located between the (n−2)^{th} sub-pixel column cln−2 and the (n−1)^{th} sub-pixel column cln−1) and the scanning signal line GT. Thus, the consistency between the sub-pixel columns can be improved, and poor picture quality caused by differences in pulling by the scanning signal can be prevented between the sub-pixel P1 close to the edge and the sub-pixel P1 located in the middle.

Illustratively, the scanning signal line GT is configured for transmitting a scanning signal which is configured for controlling turning on or turning off of the thin film transistor located in the sub-pixel P1. Therefore, the voltage magnitude of the scanning signal is related to characteristics such as the turn-on voltage of the thin film transistor. The turn-on voltage of the thin film transistor may be, for example, 17 V, 18 V, 20 V, 30 V, and 35 V, etc., which can be determined according to actual requirements.

Illustratively, each transfer signal line SW located within the display region AA is connected to only one scanning signal line GT. Thus, the consistency of the environment on both sides of each sub-pixel P1 in the display panel can be ensured.

In a specific implementation, the scanning signal is a pulse waveform with a pulse amplitude of a turn-on voltage VGH or a turn-off voltage VGL. Since the voltage value of the turn-on voltage VGH or the turn-off voltage VGL is relatively large, the electric field formed may affect the deflection of the liquid crystal, which may in turn cause poor light leakage, etc.

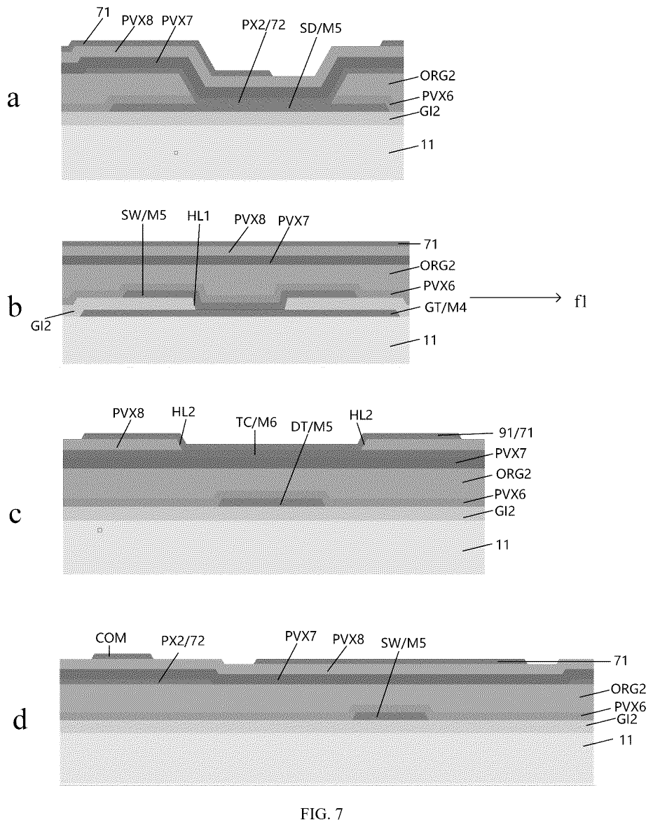

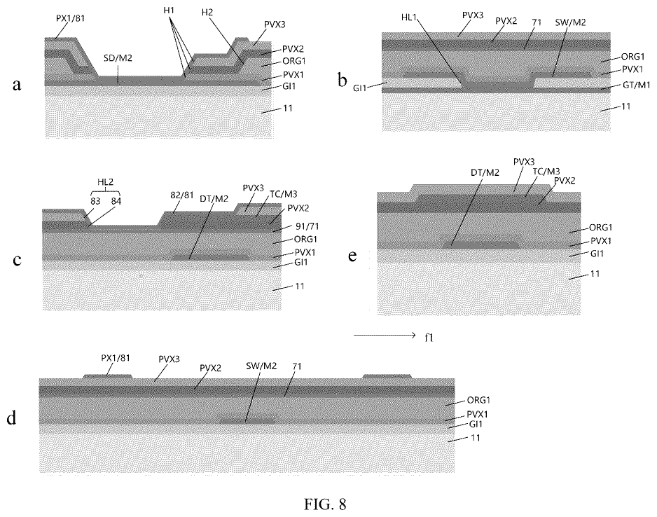

In order to improve light leakage, in some embodiments, as shown in FIG. 7 or panel b or panel d of FIG. 8, the scanning signal line GT is located between the transfer signal line SW and the base substrate 11. The display region AA further includes a common electrode layer 71 located on the side of the transfer signal line SW away from the base substrate 11, which includes a plurality of common electrodes COM. In an orthographic projection on the base substrate 11, the common electrode layer 71 covers the transfer signal line SW at least in the first direction f1.

In this embodiment, the common electrode layer 71 is configured for transmitting a voltage stabilization signal. The common electrode layer 71 is provided on the side of the transfer signal line SW away from the base substrate 11, and the common electrode layer 71 covers the transfer signal line SW at least in the first direction f1. The common electrode layer 71 can shield the electric field formed by the scanning signal and reduce the influence on the deflection of liquid crystal, thereby improving the poor light leakage.

In some embodiments, the scanning signal line GT is located between the transfer signal line SW and the base substrate 11, as shown in FIG. 7 or panel b of FIG. 8. As shown in FIG. 2 or FIG. 3, the display region AA further includes a plurality of touch control signal lines TC extending in the second direction f2. As shown in panel c of FIG. 7, panel c or panel e of FIG. 8, the touch control signal line TC is located on the side of the data signal line DT away from the base substrate 11. In the orthographic projection on the base substrate 11, the touch control signal line TC covers the data signal line DT at least in the first direction f1.

In this embodiment, the touch control signal line TC is provided on the side of the data signal line DT facing away from the base substrate 11, and the touch control signal covers the data signal line DT at least in the first direction f1, so that the influence of the touch control signal line TC on the aperture ratio can be reduced.

In some embodiments, as shown in FIG. 7 or panel c of FIG. 8, the display region AA further includes the common electrode layer 71 located between the data signal line DT and the touch control signal line TC (as shown in panel c of FIG. 8,), or on the side of the touch control signal line TC away from the base substrate 11 (as shown in panel c of FIG. 7).

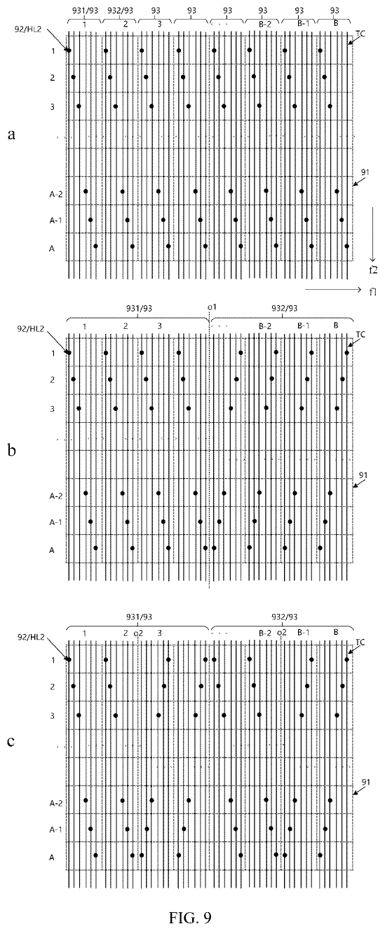

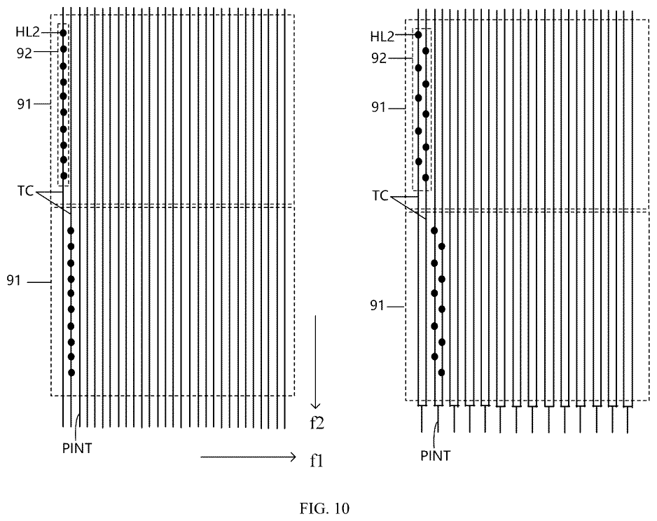

As shown in FIG. 9, the common electrode layer 71 includes a plurality of touch control sub-blocks 91 separated from each other, and the touch control sub-blocks 91 include a plurality of common electrodes COM connected to each other. As shown in FIG. 10, the touch control sub-block 91 is connected to one touch control signal line TC (as shown in the left panel of FIG. 10) or a plurality of adjacent touch control signal lines TC (two as shown in the right panel of FIG. 10) through a touch control hole HL2. As shown in the right panel of FIG. 10, a plurality of touch control signal lines TC connected to the same touch control sub-block 91 are connected to the same touch control signal terminal PINT, and touch control signal lines TC connected to different touch control sub-blocks 91 are connected to different touch control signal terminals PINT.

In the present embodiment, since the touch control signal line TC is connected to the common electrode layer 71, and the common electrode layer 71 is configured for transmitting a voltage stabilization signal, the touch control signal line TC can also serve to shield the data signal.

In some embodiments, as shown in panel c of FIG. 8, the common electrode layer 71 is located between the data signal line DT and the touch control signal line TC, and the display region AA further includes a first pixel electrode layer 81 located on the side of the touch control signal line TC away from the base substrate 11.

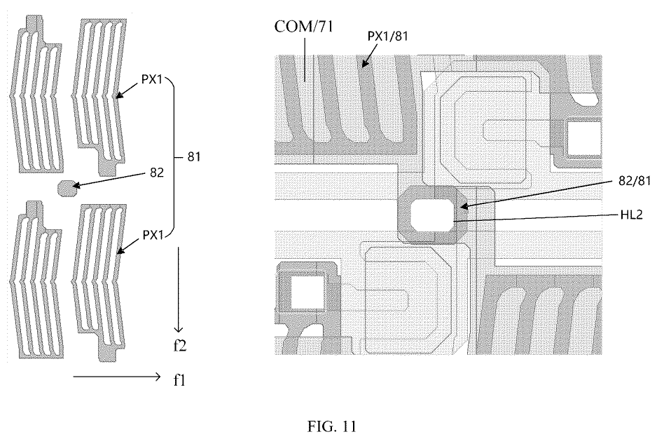

As shown in FIG. 11, the first pixel electrode layer 81 includes a plurality of first pixel electrodes PX1 separated from each other, and a transfer electrode 82 separated from the first pixel electrode PX1. The plurality of first pixel electrodes PX1 may be located within different sub-pixels P1.

In FIG. 11, a schematic view of a plane structure of the first pixel electrode layer 81 is shown in the left panel, and a partially enlarged view of the display substrate shown in FIG. 3 at the position of the dashed circle 3 is shown in the right panel.

Illustratively, as shown in FIG. 8, the display region AA includes a base substrate 11, a first metal layer M1, a first active layer ACT1, a first insulating layer GI1, a second metal layer M2, a second insulating layer PVX1, a first organic insulating film layer ORG1, a common electrode layer 71, a third insulating layer PVX2, a third metal layer M3, a fourth insulating layer PVX3 and a first pixel electrode layer 81 which are stacked and provided in sequence. The first metal layer M1 includes a scanning signal line GT, the second metal layer M2 includes a data signal line DT, a transfer signal line SW, and a source and a drain SD of the thin film transistor, and the third metal layer M3 includes a touch control signal line TC.

Illustratively, the common electrode layer 71 and the first pixel electrode layer 81 are made of transparent conductive materials such as indium tin oxide.

FIG. 3 is a circuit layout of the display substrate shown in FIG. 8. In FIG. 8, panel a shows a schematic view of the cross-sectional structure of the display substrate shown in FIG. 3 at the position of the dashed circle 1; panel b shows a schematic view of the cross-sectional structure of the display substrate shown in FIG. 3 at the position of the dashed circle 2; panel c shows a schematic view of the cross-sectional structure of the display substrate shown in FIG. 3 at the position of the dashed circle 3; panel d shows a schematic view of the cross-sectional structure of the display substrate shown in FIG. 3 at the position of the dashed line 4, and panel e shows a schematic view of the cross-sectional structure of the display substrate shown in FIG. 3 at the position of the dashed line 5.

As shown in panel a of FIG. 8, in the same sub-pixel P1, the first pixel electrode PX1 is connected to the source and the drain SD of the thin film transistor via a first via hole H1 provided on the fourth insulating layer PVX3, the third insulating layer PVX2 and the second insulating layer PVX1. The first via hole H1 forms a sleeve hole with a second via hole H2 provided on the first organic insulating film layer ORG1, and a hole wall of the second via hole H2 is located at the periphery of the first via hole H1.

As shown in panel b of FIG. 8, the transfer signal line SW and the scanning signal line GT are connected through a transfer hole HT1 provided on the first insulating layer GI1.

As shown in panel c of FIG. 8, the touch control hole HL2 includes a half hole 83 and a first through hole 84. The transfer electrode 82 is connected to the touch control signal line TC via the half hole 83, and the transfer electrode 82 is connected to the touch control sub-block 91 via the first through hole 84. In this way, the transfer electrodes 82 are respectively connected to the touch control signal line TC and the touch control sub-block 91, thereby realizing the connection between the touch control signal line TC and the touch control sub-block 91.

Illustratively, in order to prevent oxidation of the touch control signal line TC, the transfer electrode 82 may completely cover the exposed touch control signal line TC within half hole 83.

Referring to the right panel of FIG. 12, a schematic flow chart of a method for preparing the display substrate shown in FIG. 3 and FIG. 8 is shown. The display substrate is prepared by a 9-step patterning process. In the right panel of FIG. 12, the second insulating layer PVX1, the third insulating layer PVX2 and the fourth insulating layer PVX3 can be prepared simultaneously by a one-step patterning process, while the remaining film layers can be prepared by the one-step patterning process respectively.

In the process of etching the material of the first organic insulating film layer ORG1, parameters can be adjusted so that the second insulating layer PVX1 is not etched, thereby ensuring that at the position where the material of the first organic insulating film layer ORG1 is excavated, the material of the second insulating layer PVX1 protects the first metal layer M1 and the second metal layer M2, thereby improving the corrosion resistance of the surrounding metal. After etching to obtain the first organic insulating film layer ORG1, the second insulating layer PVX1, the third insulating layer PVX2 and the fourth insulating layer PVX3 can be formed by the one-step patterning process.

In the disclosure, the patterning process may include, for example, one or more of film forming, exposing, developing, and etching steps, and the disclosure is not limited thereto.

In some embodiments, as shown in panel c of FIG. 7, the common electrode layer 71 is located on the side of the touch control signal line TC away from the base substrate 11, and the touch control sub-block 91 is connected to the touch control signal line TC via the touch control hole HL2.

Illustratively, as shown in FIG. 7, the display substrate includes a base substrate 11, a fourth metal layer M4, a second active layer ACT2, a fifth insulating layer GI2, a fifth metal layer M5, a sixth insulating layer PVX6, a second organic insulating film layer ORG2, a second pixel electrode layer 72, a seventh insulating layer PVX7, a sixth metal layer M6, an eighth insulating layer PVX8 and a common electrode layer 71 which are stacked and provided in sequence. The fourth metal layer M4 includes a scanning signal line GT, the fifth metal layer M5 includes a data signal line DT, a transfer signal line SW, and a source and a drain SD of the thin film transistor, and the sixth metal layer M6 includes a touch control signal line TC.

In this embodiment, the second pixel electrode layer 72 includes a plurality of second pixel electrodes PX2 located within different sub-pixels P1.

Illustratively, the common electrode layer 71 and the second pixel electrode layer 72 are made of transparent conductive materials such as indium tin oxide.

FIG. 2 shows a circuit layout of the display substrate shown in FIG. 7. In FIG. 7, panel a shows a schematic view of the cross-sectional structure of the display substrate shown in FIG. 2 at the position of the dashed circle 1, panel b shows a schematic view of the cross-sectional structure of the display substrate shown in FIG. 2 at the position of the dashed circle 2, panel c shows a schematic view of the cross-sectional structure of the display substrate shown in FIG. 2 at the position of the dashed circle 3, and panel d shows a schematic view of the cross-sectional structure of the display substrate shown in FIG. 2 at the position of the dashed line 4.

As shown in panel a of FIG. 7, in the same sub-pixel P1, the second pixel electrode PX2 is connected to the source and the drain SD of the thin film transistor via a via hole provided on the second organic insulating film layer ORG2 and the sixth insulating layer PVX6. The via holes provided on the second organic insulating film layer ORG2 and the sixth insulating layer PVX6 can be formed simultaneously by the 9-step patterning process. Since the thickness of the film layer through which the via hole connecting the second pixel electrode PX2 and the source and the drain SD of the thin film transistor passes is small, a via hole with a smaller aperture can be prepared, thereby improving the aperture ratio.

As shown in panel b of FIG. 7, the transfer signal line SW and the scanning signal line GT are connected through a transfer hole HT1 provided on the fifth insulating layer GI2.

As shown in panel c of FIG. 7, a touch control sub-block 91 is connected to a touch control signal line TC via a touch control hole HL2 provided on the eighth insulating layer PVX8.

Referring to the left panel of FIG. 12, a schematic flow chart of a method for preparing the display substrate shown in FIG. 2 and FIG. 7 is shown. The display substrate is prepared by the nine-step patterning process. In the left panel of FIG. 12, the seventh insulating layer PVX7 and the eighth insulating layer PVX8 can be prepared simultaneously by the one-step patterning process; the sixth insulating layer PVX6 and the second organic insulating film layer ORG2 can be prepared simultaneously by the one-step patterning process; and the remaining film layers can be prepared by the one-step patterning process respectively.

In some embodiments, as shown in FIG. 9, a plurality of touch control sub-blocks 91 are arranged in an array in the first direction f1 and the second direction f2, the plurality of touch control sub-blocks 91 are divided into a plurality of touch control regions 93 arranged in the first direction f1, and the touch control regions 93 include one or more adjacent columns of the touch control sub-blocks 91. The plurality of touch control regions 93 include a first touch control region 931 and a second touch control region 932. A plurality of touch control holes HL2 located in the first touch control region 931 are axially symmetric or translationally symmetric with a plurality of touch control holes HL2 located in the second touch control region 932.

As shown in FIG. 9 and FIG. 10, a touch control unit 92 includes a plurality of touch control holes HL2 connected to the same touch control sub-block 91. Touch control units 92 connected to different touch control sub-blocks 91 have the same quantity of touch control holes HL2, and the touch control holes HL2 have the same arrangement.

The translation symmetry of the plurality of touch control holes HL2 located in the first touch control region 931 with the plurality of touch control holes HL2 located in the second touch control region 932 means that the plurality of touch control holes HL2 located in the first touch control region 931 can substantially coincide with the positions of the plurality of touch control holes HL2 located in the second touch control region 932 by translating in the first direction f1.

Illustratively, as shown in panel a of FIG. 9, one touch control region 93 includes a column of touch control sub-blocks 91, and the plurality of touch control holes HL2 located in the first touch control region 931 are translationally symmetric with the plurality of touch control holes HL2 located in the second touch control region 932. The first touch control region 931 and the second touch control region 932 may be any two touch control regions 93.

Illustratively, as shown in panel b of FIG. 9, one touch control region 93 includes four columns of touch control sub-blocks 91, and the plurality of touch control holes HL2 located in the first touch control region 931 are axially symmetric with the plurality of touch control holes HL2 located in the second touch control region 932, and the symmetry axis o1 can be, for example, a symmetry axis extending in the second direction f2 of the orthographic projection of the display region AA on the base substrate 11. In this example, in the same touch control region 93, the touch control holes HL2 located in different columns of touch control sub-blocks 91 can be translationally symmetric.

Illustratively, as shown panel c of FIG. 9, one touch control region 93 includes four columns of touch control sub-blocks 91, and the plurality of touch control holes HL2 located in the first touch control region 931 are translationally symmetric with the plurality of touch control holes HL2 located in the second touch control region 932. In this example, four columns of touch control sub-blocks 91 in the same touch control region 93 can be axially symmetrically provided, and the symmetry axis o2 is a symmetry axis extending in the second direction f2 of the orthographic projection of the touch control region 93 on the base substrate 11.

Illustratively, as shown in FIG. 10, a touch control signal line TC and a touch control sub-block 91 can be connected via a plurality of touch control holes HL2, and these touch control holes HL2 are uniformly distributed in the second direction f2. For example, one touch control hole HL2 can be provided for every four sub-pixels P1.

Illustratively, as shown in FIG. 10, the quantity of touch control holes HL2 connected to each touch control sub-block 91 is a preset quantity, which may be greater than or equal to 5 and less than or equal to 20, for example. In FIG. 10, the preset quantity is 10. In the case where the same touch control sub-block 91 is connected to two adjacent touch control signal lines TC, the quantity of touch control holes HL2 provided on each touch control signal line TC is one-half of the preset quantity.

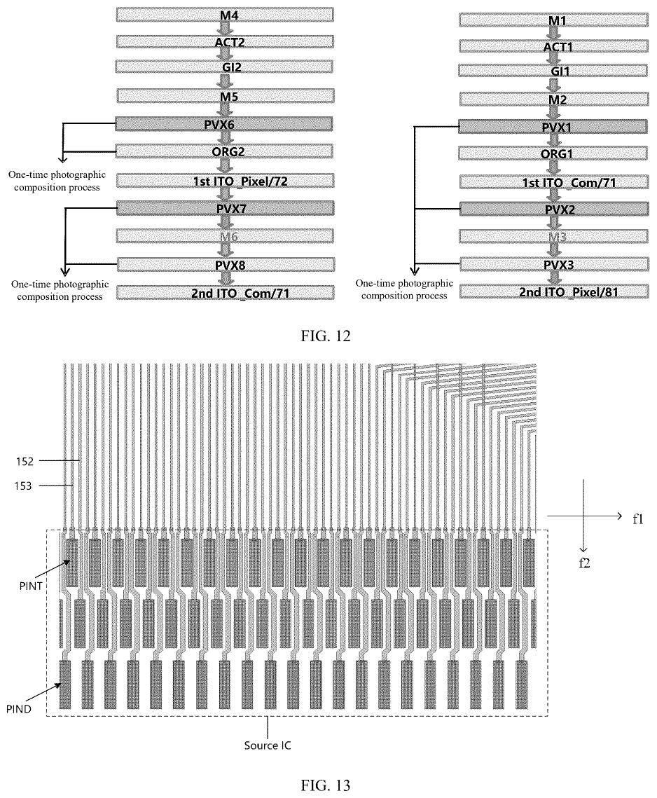

In some embodiments, as shown in FIG. 13, the frame region BA includes: a touch control signal terminal PINT provided on the same layer as the touch control signal line TC and connected to each other for providing a touch control signal to the touch control signal line TC; and a data signal terminal PIND provided on the same layer as the data signal line DT and connected to each other for supplying a data signal to the data signal line DT. The touch control signal terminal PINT is located between the plurality of data signal terminals PIND, and both the touch control signal terminal PINT and the data signal terminal PIND are configured for binding the source drive chip Source IC.

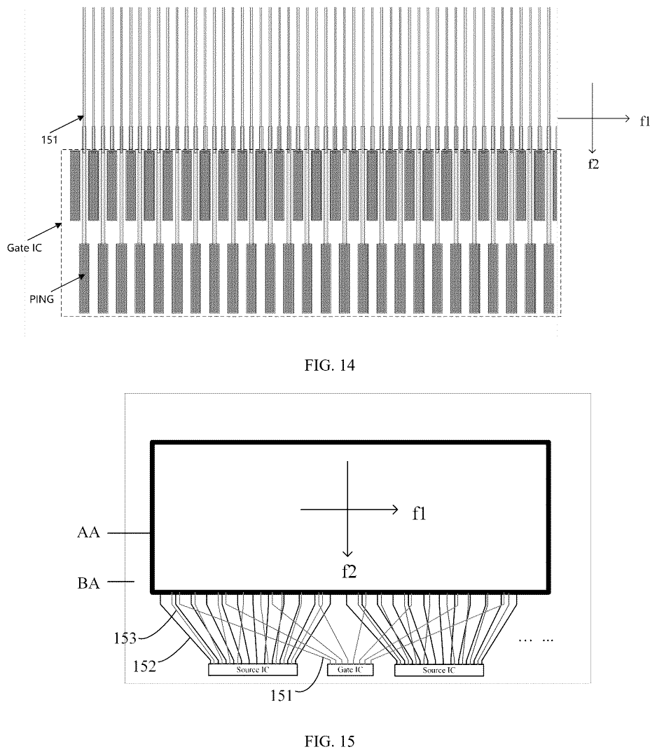

In some embodiments, as shown in FIG. 13 and FIG. 14, the frame region BA includes: a scanning signal terminal PING provided on the same layer as the scanning signal line GT and connected to the transfer signal line SW through a via hole for providing a scanning signal to the transfer signal line SW and the scanning signal line GT; and a data signal terminal PIND provided on the same layer as the data signal line DT and connected to each other for providing a data signal to the data signal line DT. The scanning signal terminal PING and the data signal terminal PIND are located on the same side of the display region AA.

Illustratively, the scanning signal terminal PING, the data signal terminal PIND, and the touch control signal terminal PINT are respectively located on different metal layers, which can be independently wired. Due to an insulating layer provided between different metal layers, in the orthographic projection on the base substrate 11, lines can be overlapped or crossed, thereby facilitating saving wiring space and reducing the frame size.

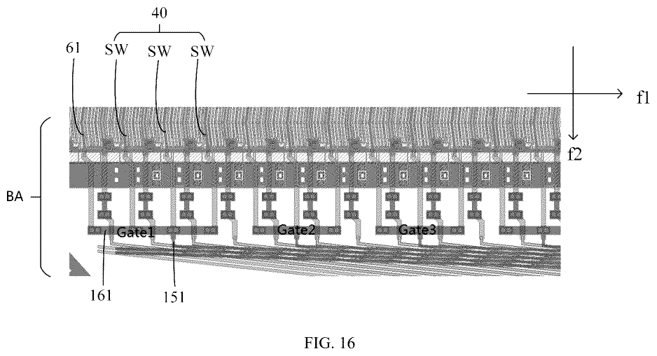

Illustratively, as shown in FIG. 15, the scanning signal terminal PING (located below the gate drive chip Gate IC in FIG. 15) is connected to the transfer signal line SW through a first lead 151 which may be provided on the same layer as the scanning signal line GT.

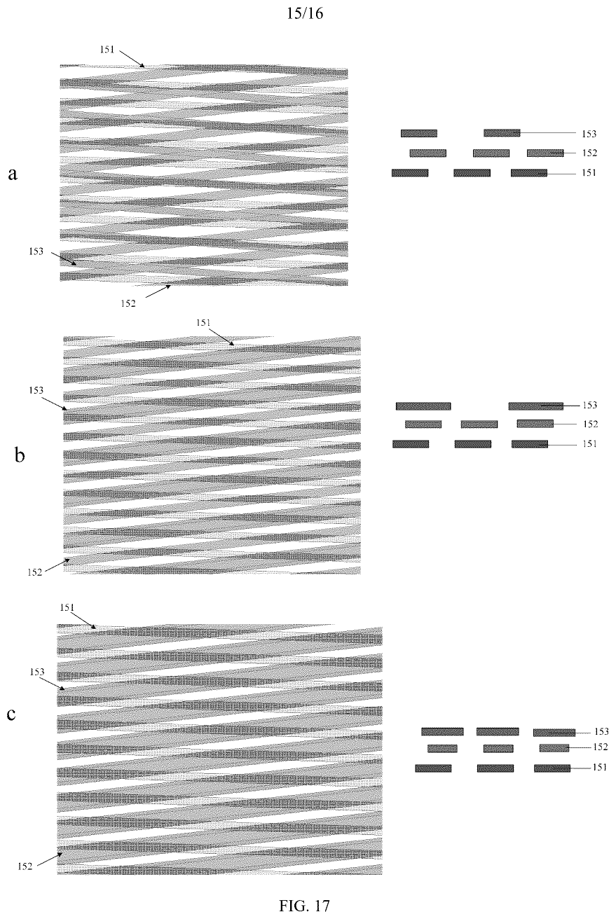

As shown in FIG. 16, a plurality of transfer signal lines SW located in the same transfer line group 40 extend to the frame region BA, are short circuited together by the short circuiting pattern 161, and then connected to the scanning signal terminal PING through the first lead 151. The shorting pattern 161 is provided on the same layer as the scanning signal line GT.

Illustratively, as shown in FIG. 15, the data signal terminal PIND (located below the source drive chip Source IC in FIG. 15) is connected to the data signal line DT through a second lead 152 which may be provided on the same layer as the data signal line DT.

Illustratively, as shown in FIG. 15, the touch control signal terminal PINT (located below the source drive chip Source IC in FIG. 15) is connected to the touch control signal line TC through a third lead 153 which may be provided on the same layer as the touch control signal line TC.

Illustratively, as shown in FIG. 15 and FIG. 17, the first lead 151, the second lead 152, and the third lead 153 may be mixed wiring, any two of them may overlap or cross each other. The disclosure is not limited thereto.

Panel a, panel b, or panel c of FIG. 17 are structural views of three different positions in the frame region BA, respectively. In panel a, panel b, or panel c, the left panel is a plane wiring layout, and the right panel is a view of the cross-sectional structure.

Illustratively, the scanning signal terminal PING may be, for example, an output port of the gate drive chip Gate IC, and may also be an output port of the gate drive circuit. For example, the gate drive circuit may include a plurality of shift registers cascaded with each other, and the scanning signal terminal PING may be an output port of the shift register.

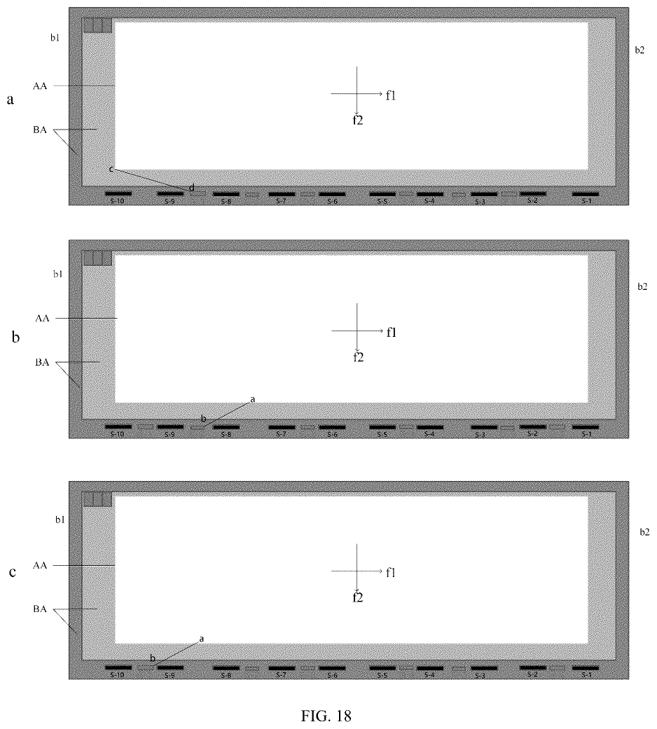

In some embodiments, as shown in FIG. 18, the plurality of scanning signal terminals PING are divided into one or more scanning signal binding areas G for binding a gate drive chip Gate IC. The plurality of data signal terminals PIND are divided into a plurality of data signal binding areas S for binding a source drive chip Source IC. The scanning signal binding area G is provided between two adjacent data signal binding areas S, at most one scanning signal binding area G is provided between two adjacent data signal binding areas S, and at most two data signal binding areas S are provided between two adjacent scanning signal binding areas G.

Thus, by arranging the scanning signal binding areas G dispersedly between the data signal binding areas S, it is advantageous to reduce the trace length of the first lead 151, save the wiring space of the first lead 151, and reduce the frame size.

Illustratively, in FIG. 18, a plurality of scanning signal terminals PING are divided into six scanning signal binding areas G, i.e., scanning signal binding areas G-1 to G-6. The plurality of data signal terminals PIND are divided into 10 data signal binding areas S, i.e., data signal binding areas S-1 to S-10.

Illustratively, as shown in FIG. 18, a plurality of data signal binding areas S may be uniformly distributed within the frame region BA in the first direction f1, which is advantageous to reduce the trace length of the second lead 152 and save wiring space.

Illustratively, the touch control signal terminal PINT is located within the data signal binding area S and between a plurality of data signal terminals PIND.

In some embodiments, as shown in FIG. 18, the plurality of data signal binding areas S includes a first data signal binding area S-10 and a second data signal binding area S-9. The first data signal binding area S-10 and the second data signal binding area S-9 are provided close to a first edge b1 (as shown in FIG. 18) or a second edge b2. The first edge b1 and the second edge b2 are two opposite edges of the display substrate in the first direction f1.

Illustratively, as shown in panel a of FIG. 18, no scanning signal binding area G is provided between the first data signal binding area S-10 and the second data signal binding area S-9. The longest first lead 151 requires a longer length from c to d, and the wiring space required for the first lead 151 is larger.

Illustratively, a scanning signal binding area G is provided between the first data signal binding area S-10 and the second data signal binding area S-9, as shown in panel b or panel c of FIG. 18. Thus, by providing the scanning signal binding area G between the first data signal binding area S-10 and the second data signal binding area S-9, the longest first lead 151 requires a shorter length from a to b, so that the wiring space of the first lead 151 can be saved.

The wiring pattern shown in panel b and panel c of FIG. 18 can save 0.9 mm of the frame size, compared to the wiring pattern shown in panel a of FIG. 18.

The disclosure provides a display panel including a cell alignment substrate, a liquid crystal layer, and a display substrate as provided in any one of the embodiments. The liquid crystal layer is located between the cell alignment substrate and the display substrate, and the display region AA is arranged close to the liquid crystal layer.

It will be appreciated by those skilled in the art that the display panel provided by the disclosure has the advantages of the display substrate described above.

The disclosure provides a display device including a display substrate as provided in any one of the embodiments; a source drive chip Source IC, which is bound and connected to the frame region BA, and is configured for providing a data signal to the data signal line DT; and one of the following: a gate drive chip Gate IC, which is bound and connected to the frame region BA and located on the same side of the display region AA as the source drive chip Source IC, and is configured for providing a scanning signal to the transfer signal line SW and the scanning signal line GT; a gate drive circuit, which is located in the frame region BA and located on the same side of the display region AA as the source drive chip Source IC, and is configured for providing a scanning signal to the transfer signal line SW and the scanning signal line GT.

It will be appreciated by those skilled in the art that the display device provided by the disclosure has the advantages of the display substrate described above.

The display device provided by the disclosure may be any product or component with a display function such as a display module, a mobile phone, a tablet computer, a television, a display, a notebook computer, a digital photo frame, a vehicle-mounted display device, an intelligent watch, a fitness wristband, and a personal digital assistant.

Illustratively, the output port of the source drive chip Source IC includes a data signal port for outputting a data signal and a touch control signal port for outputting a touch control signal.

Illustratively, the output port of the gate drive chip Gate IC includes a scanning signal port for outputting a scanning signal.

In the present disclosure, unless stated otherwise, the meaning of “multiple” is “two or more”, and the meaning of “at least one” is “one or more”.

In the present disclosure, it should be understood that an orientation or positional relationship indicated by terms “upper” and “lower” is based on an orientation or positional relationship shown in the drawings, and is merely for convenience of describing the present disclosure and simplifying the description, rather than indicates or implies that the device or element referred to must have a specific orientation, be configured and operated in a specific orientation, and thus cannot be understood as limitation on the present disclosure.

In the present disclosure, the terms “including”, “comprising” or any variations thereof are intended to embrace a non-exclusive inclusion, such that a process, method, article, or terminal device including a plurality of elements includes not only those elements but also includes other elements not expressly listed, or also includes elements inherent to such a process, method, article, or device. In the absence of further limitation, an element defined by the phrase “including a . . . ” does not exclude the presence of additional identical element in the process, method, article, or terminal device.

In the present disclosure, the terms “one embodiment”, “some embodiments”, “exemplary embodiments”, “example”, “specific example” or “some examples” are intended to indicate that specific features, structures, materials or characteristics related to the embodiment or example are comprised in at least one embodiment or example of the present application. The illustrative indication of the above terms does not necessarily refer to the same one embodiment or example. Moreover, the specific features, structures, materials or characteristics may be comprised in any one or more embodiments or examples in any suitable manner.

In the present disclosure, the relational terms such as first and second are used only to distinguish one entity or operation from another without necessarily requiring or implying any such actual relationship or order between these entities or operations.

In the description on some embodiments, “couple” and “connect” and the derivatives thereof may be used. For example, in the description on some embodiments, the term “connect” may be used to indicate that two or more components directly physically contact or electrically contact. As another example, in the description on some embodiments, the term “couple” may be used to indicate that two or more components directly physically contact or electrically contact. However, the term “couple” or “communicatively coupled” may also indicate that two or more components do not directly contact, but still cooperate with each other or act on each other. The embodiments disclosed herein are not necessarily limited by the contents herein.

“At least one of A, b and C” and “at least one of A, b or C” have the same meaning, and both of them include the following combinations of A, b and C: solely A, solely B, solely C, the combination of A and B, the combination of A and C, the combination of B and C, and the combination of A, b and C.

“A and/or B” include the following three combinations: solely A, solely B, and the combination of A and B.

As used herein, with reference to the context, the term “if” is optionally interpreted as meaning “when” or “in response to determining that” or “in response to detecting that”. Similarly, with reference to the context, the phrase “if it is determined that” or “if the stated condition or event has been detected” is optionally interpreted as referring to “when it is determined that” or “in response to determining . . . ” or “when the stated condition or event has been detected” or “in response to the stated condition or event having been detected”.

The “configured to” or “configured for” as used herein is intended as opened and inclusive languages, and does not exclude apparatuses configured to perform or configured for performing additional tasks or steps.

In addition, the “based on” and “according to” as used is intended as opened and inclusive, because a process, step, calculation or other action “based on” one or more described conditions or values may, in practice, be based on an additional condition or exceed the described values. A process, step, calculation, or other action according to one or more described conditions or values may, in practice, accord to an additional condition or exceed the described values.

As used herein, “about”, “substantially” or “approximately” includes the described value as well as an average value within an acceptable range of deviation from a particular value, the acceptable range of deviation is as determined by one of ordinary skill in the art taking into account the measurement in question and the error associated with the measurement of the particular quantity (i.e., limitations of the measurement system).

As used herein, “parallel”, “perpendicular”, “equal” and “flush” include the described situations as well as situations that are similar to the described situations and within an acceptable range of deviation. The acceptable range of deviation is determined by one of ordinary skill in the art taking into account the measurement in question as well as errors associated with the measurement of a particular quantity (i.e., the limitations of the measurement system). For example, “parallel” includes absolutely parallel and approximately parallel, where an acceptable range of deviation for approximately parallel may be, for example, within a deviation of 5°. “Perpendicular” includes absolutely perpendicular and approximately perpendicular, where an acceptable range of deviation for approximately perpendicular may also be, for example, within a deviation of 5°. “Equal” includes absolutely equal and approximately equal, where an acceptable range of deviation for approximately equal may be, for example, that the difference between the two that are equal is less than or equal to 5% of either. “Flush” includes absolutely flush and approximately flush, where an acceptable range of deviation for approximately flush may be, for example, that the distance between the two that are flush is less than or equal to 5% of the size of either.

It should be understood that when a layer or element is referred to as being on another layer or substrate, the layer or element may be directly on another layer or substrate, or there is an intermediate layer between the layer or element and another layer or substrate.

Exemplary embodiments are described herein with reference to sectional and/or planar views as idealized exemplary drawings. In the drawings, the thicknesses of the layers and regions are enlarged for clarity. Therefore, variations in shape relative to the drawings due to, for example, manufacturing techniques and/or tolerances can be envisaged. Thus, exemplary embodiments should not be construed as being limited to the shapes of the regions herein, but rather include shape deviations due to, for example, manufacturing. For example, etched regions shown as rectangular will typically have curved features. Accordingly, the regions shown in the drawings are essentially schematic and their shapes are not intended to illustrate the actual shapes of the regions of the device and are not intended to limit the scope of the exemplary embodiments.

Finally, it should be noted that the above embodiments are merely intended to explain the technical solutions of the present disclosure, and not to limit them. Although the present disclosure is explained in detail with reference to the above embodiments, a person skilled in the art should understand that he can still modify the technical solutions set forth by the above embodiments, or make equivalent substitutions to part of the technical features of them. However, those modifications or substitutions do not make the essence of the corresponding technical solutions depart from the spirit and scope of the technical solutions of the embodiments of the present disclosure.

1. A display substrate, comprising a base substrate, and a display region and a frame region located on a side of the base substrate, wherein the display region comprises:
a plurality of scanning signal lines extending in a first direction, a plurality of transfer signal lines extending in a second direction, and a plurality of data signal lines extending in the second direction, wherein the first direction and the second direction cross each other; and
wherein the scanning signal lines are provided on a different layer from the data signal lines, the scanning signal lines are provided on a different layer from the transfer signal lines, the data signal lines are provided on the same layer as the transfer signal lines, the scanning signal lines are connected to at least one of the transfer signal lines, and different scanning signal lines are connected to different transfer signal lines.

2. The display substrate according to claim 1, wherein the plurality of scanning signal lines comprise a first scanning signal line and a second scanning signal line, and a quantity of transfer signal lines connected to the first scanning signal line is equal to a quantity of transfer signal lines connected to the second scanning signal line.

3. The display substrate according to claim 1, wherein the plurality of transfer signal lines are divided into a plurality of transfer line groups arranged in the first direction, and the transfer line groups comprise one or more adjacent transfer signal lines; and
transfer signal lines located in the same transfer line group are connected to the same scanning signal terminal and the same scanning signal line, and transfer signal lines located in different transfer line groups are connected to different scanning signal terminals and different scanning signal lines.

4. The display substrate according to claim 3, wherein the plurality of scanning signal lines comprise a third scanning signal line and a fourth scanning signal line, and the same quantity of transfer line groups are provided between two transfer line groups connected to and adjacent to the third scanning signal line, and between two transfer line groups connected to and adjacent to the fourth scanning signal line.

5. The display substrate according to claim 3, wherein the plurality of scanning signal lines comprise a fifth scanning signal line and a sixth scanning signal line, a first quantity of transfer line groups are provided between two transfer line groups connected to and adjacent to the fifth scanning signal line, a second quantity of transfer line groups are provided between two transfer line groups connected to and adjacent to the sixth scanning signal line, and the first quantity is greater than or less than the second quantity.

6. The display substrate according to claim 5, wherein the plurality of scanning signal lines further comprise a seventh scanning signal line, the sixth scanning signal line is located between the fifth scanning signal line and the seventh scanning signal line, and a third quantity of transfer line groups are provided between two transfer line groups connected to and adjacent to the seventh scanning signal line; and
wherein the first quantity, the second quantity, and the third quantity increase or decrease in sequence.

7. The display substrate according to claim 3, wherein the plurality of transfer line groups comprise a first transfer line group, a second transfer line group and a third transfer line group which are connected to the same scanning signal line and are sequentially arranged in the first direction; and
wherein a quantity of transfer line groups provided between the first transfer line group and the second transfer line group is equal to a quantity of transfer line groups provided between the second transfer line group and the third transfer line group.

8. (canceled)

9. (canceled)

10. The display substrate according to claim 3, wherein the plurality of transfer line groups comprise a tenth transfer line group and an eleventh transfer line group connected to the same scanning signal line, the tenth transfer line group and the eleventh transfer line group are axially symmetrically provided about a first axis, and the first axis is a symmetry axis extending in the second direction of an orthographic projection of the display region on the base substrate.

11. The display substrate according to claim 3, wherein the scanning signal lines and the transfer signal lines are connected via transfer holes, and transfer holes connecting all transfer signal lines in the same transfer line group constitute a transfer hole group; and
in an orthographic projection on the base substrate, a plurality of transfer hole groups are arranged in a shape comprising at least one of the following: a V-shape, an inverted V-shape, an N-shape, an inverted N-shape, a strip extending in a third direction, a plurality of strips extending in the third direction and parallel to each other, and the third direction is provided crosswise to the first direction and the second direction, respectively.

12. The display substrate according to claim 3, wherein a quantity of transfer signal lines contained in the transfer line group is M or M+1, the M is a positive integer obtained by rounding down m*3/(2N*2n), the m is a row resolution of the display region, the n is a column resolution of the display region, and the N is a quantity of transfer line groups connected to the same scanning signal line; and/or
difference between quantities of transfer signal lines contained in different transfer line groups is less than or equal to 1; and/or
quantities of transfer line groups connected to different scanning signal lines are the same.

13. The display substrate according to claim 3, wherein the scanning signal lines and the transfer signal lines are connected via transfer holes, and transfer holes connecting all transfer signal lines in the same transfer line group constitute a transfer hole group; and
a plurality of transfer hole groups are divided into a plurality of transfer units arranged in the first direction, each of the transfer units comprises the same quantity of transfer hole groups, the plurality of transfer units comprise a first transfer unit and a second transfer unit, and the first transfer unit and the second transfer unit are translationally symmetric or axially symmetric.

14. (canceled)

15. The display substrate according to claim 1, wherein the scanning signal lines are located between the transfer signal lines and the base substrate, and the display region further comprises:
a common electrode layer located on a side of the transfer signal lines away from the base substrate, comprising a plurality of common electrodes; and
wherein in an orthographic projection on the base substrate, the common electrode layer covers the transfer signal lines at least in the first direction.

16. The display substrate according to claim 1, wherein the scanning signal lines are located between the transfer signal lines and the base substrate, and the display region further comprises:
a plurality of touch control signal lines extending in the second direction, wherein the touch control signal lines are located on a side of the data signal lines away from the base substrate, and in an orthographic projection on the base substrate, the touch control signal lines cover the data signal lines at least in the first direction.

17. The display substrate according to claim 16, wherein the display region further comprises:
a common electrode layer, located between the data signal lines and the touch control signal lines, or located on a side of the touch control signal lines away from the base substrate, comprising a plurality of touch control sub-blocks separated from each other, wherein the touch control sub-blocks comprise a plurality of common electrodes connected to each other; and
wherein the touch control sub-blocks are connected to one or more adjacent touch control signal lines via touch control holes, a plurality of touch control signal lines connected to the same touch control sub-block are connected to the same touch control signal terminal, and touch control signal lines connected to different touch control sub-blocks are connected to different touch control signal terminals.

18. The display substrate according to claim 17, wherein the common electrode layer is located between the data signal lines and the touch control signal lines, and the display region further comprises:
a first pixel electrode layer, located on a side of the touch control signal lines away from the base substrate, comprising a plurality of first pixel electrodes separated from each other and a transfer electrode separated from the first pixel electrodes; and
the touch control holes comprising a half hole and a first through hole, wherein the transfer electrode and the touch control signal lines are connected via the half hole, and the transfer electrode and the touch control sub-blocks are connected via the first through hole.

19. (canceled)

20. The display substrate according to claim 16, wherein the frame region comprises:
a touch control signal terminal, provided on the same layer as the touch control signal lines and connected to each other, for providing a touch control signal to the touch control signal lines; and
a data signal terminal, provided on the same layer as the data signal lines and connected to each other, for providing a data signal to the data signal lines; and
wherein the touch control signal terminal is located between the plurality of data signal terminals, and the touch control signal terminal and the data signal terminal are both configured for binding a source drive chip.

21. The display substrate according to claim 1, wherein the frame region comprises:
a scanning signal terminal, provided on the same layer as the scanning signal lines and connected to the transfer signal lines through a via hole, for providing a scanning signal to the transfer signal lines and the scanning signal lines; and
a data signal terminal, provided on the same layer as the data signal line and connected to each other, for providing a data signal to the data signal lines; and
wherein the scanning signal terminal and the data signal terminal are located on the same side of the display region.

22. The display substrate according to claim 21, wherein a plurality of the scanning signal terminals are divided into one or more scanning signal binding areas which are configured for binding a gate drive chip;
a plurality of the data signal terminals are divided into a plurality of data signal binding areas, and the data signal binding areas which are configured for binding a source drive chip; and
wherein the scanning signal binding areas are provided between two adjacent data signal binding areas, and at most one of the scanning signal binding areas is provided between two adjacent data signal binding areas, and at most two of the data signal binding areas are provided between two adjacent scanning signal binding areas.

23. (canceled)

24. A display panel, comprising: a cell alignment substrate, a liquid crystal layer, and the display substrate according to claim 1, wherein the liquid crystal layer is located between the cell alignment substrate and the display substrate, and the display region is provided close to the liquid crystal layer.

25. A display device, comprising:
the display substrate according to claim 1;
a source drive chip, bound and connected to the frame region, for providing a data signal to the data signal line; and one of the following:
a gate drive chip, bound and connected to the frame region, and located on the same side of the display region as the source drive chip, for providing a scanning signal to the transfer signal line and the scanning signal line;
a gate drive circuit, located in the frame region, and located on the same side of the display region as the source drive chip, for providing a scanning signal to the transfer signal line and the scanning signal line.
